(19) United States
(12) Patent Application Publication
(10) Pub. No.: US 2022/0148908 A1
(43) Pub. Date: May 12, 2022

(54) METHOD FOR FORMING A USEFUL SUBSTRATE TRAPPING STRUCTURE

(71) Applicant: COMMISSARIAT A L'ENERGIE ATOMIQUE ET AUX ENERGIES ALTERNATIVES, Paris (FR)

(72) Inventors: Emmanuel Augendre, Grenoble Cedex 09 (FR); François Andrieu, Grenoble Cedex 09 (FR); Cédric Taillandier, Grenoble Cedex 09 (FR)

(73) Assignee: COMMISSARIAT A L'ENERGIE ATOMIQUE ET AUX ENERGIES ALTERNATIVES, Paris (FR)

(21) Appl. No.: 17/454,091

(22) Filed: Nov. 9, 2021

(30) Foreign Application Priority Data
Nov. 10, 2020 (FR) 20 11552

(51) Int. Cl. H01L 21/763; H01L 21/762

(52) U.S. Cl. CPC H01L 21/763; H01L 21/76254

(57) ABSTRACT

The invention relates to a method of forming a trapping structure of a useful substrate designed to trap charges and limit at least one of crosstalk, radio frequency losses, and distortions of a device that may be formed on or in the useful substrate. Formation of the trapping structure includes forming a first layer that includes amorphous silicon carbide and forming a second layer covering the first layer that comprises an insulating or semiconductor material in an amorphous state and having a crystallisation temperature lower than that of the amorphous silicon carbide.

### TECHNICAL FIELD

This invention relates to the field of substrates for micro-electronics and radio frequency (“RF”). In particular, this invention relates to the field of silicon on insulator (“SOI”) substrates, and in particular substrates provided with a trapping layer intercalated between a support substrate and a stack formed from an insulating layer and a silicon layer.

In this regard, this invention aims to disclose a method for manufacturing an HR SOI substrate that can limit, or even prevent, any degradation to trapping when the substrate is heat treated.

### STATE OF PRIOR ART

Silicon on insulator (“SOI”) substrates are now widely used, and have been for several years, for the manufacture of microelectronic devices.

These substrates 1 comprise an insulating layer 3, intercalated between a silicon layer 4 and a support substrate 2, designed to electrically isolate the components (particularly transistors) of the same microelectronic device (FIG. 1).

However, when manufacturing radio frequency (hereinafter referred to as “RF”) devices, for example for mobile applications and particularly for mobile telephony, this single insulating layer is no longer sufficient to guarantee optimal operation of said devices. When they are in operation, they are the site of parasite phenomena that disturb their operation and de facto affect their performances. Crosstalk, non-linearities and eddy currents are the most common parasitic phenomena likely to be observed.

A new type of SOI substrate, called an RF SOI substrate, has been proposed in order to give a positive response to these problems, or at least to limit their effects (FIG. 2). This RF SOI substrate comprises a trap-rich layer 3′ intercalated between the insulating layer 3 and the support substrate 2. The trap-rich layer 3′ comprises polycrystalline silicon for this purpose. In other words, the polycrystalline silicon layer comprises monocrystalline silicon grains bonded together by grain boundaries.

The effectiveness of this trap-rich layer 3′ in reducing or even eliminating parasite phenomena is closely related to its defects density. In particular, as the defects density increases, the trap-rich layer 3′ becomes more effective in reducing parasite phenomena within an RF device.

In this regard, it is known that said traps are located essentially at grain boundaries in the trap-rich layer 3′. However, when the grains heat treated, they grow so that the density of grain boundaries is directly affected.

In order to overcome this problem and as described in document [1] cited at the end of the description, it has been proposed to have an oxide layer between the trap-rich layer 3′ and the support substrate 2, designed to slow the growth of grains in the trap-rich layer 3′.

However, the oxide layer must be sufficiently thin so that free carriers can pass through it and be trapped . However, being thin makes this layer sensitive to a dissolution phenomenon when annealed at high temperature, for example at 1100° C. Alternatively, having a carbonated layer between the trap-rich layer 3′ and the support substrate 2 could be considered, in order to block growth of grains in the trap-rich layer 3′ (document [2] cited at the end of the description).

However, even in the presence of this carbonated layer, the size of these grains in the trap-rich layer increases laterally, when it is heat treated. Thus with this alternative, it is necessary to consider a relatively thin trap-rich layer, for example between 100 nm and 1000 nm thick, and consequently limit its trapping properties.

Alternatively, as described in document [3] cited at the end of the description, a trap-rich layer that includes silicon doped with carbon (the atomic content of carbon being less than 15%) may be considered. resting on an interface insulation layer (thus placed between the trap-rich layer and the support substrate). The carbon thus limits the lateral growth of grains in the trap-rich layer, while the interface layer limits their growth along the thickness of the trap-rich layer. However this configuration is not satisfactory.

The interface layer, that generally comprises oxynitride, may contain positive charges that will attract excess free electrons at the interface (as stated in document [4] cited at the end of the description).

Moreover, during a high temperature heat treatment, the trap-rich layer can crystallise spontaneously forming grains with a size comparable with the thickness of said layer.

Thus, one purpose of this invention is to disclose a method of forming a trapping structure with reduced sensitivity to heat treatments.

Another purpose of this invention is to disclose a method for forming a trapping structure that can limit disturbances that could occur between free carriers and the traps of the trapping structure.

Another purpose of this invention is to disclose a method for forming an HR SOI substrate provided with a trapping structure with reduced sensitivity to heat treatments.

Another purpose of this invention is to disclose a method for manufacturing an HR SOI substrate in which there is a trapping structure capable of limiting disturbances that might occur between free carriers and the traps in the trapping structure.

### PRESENTATION OF THE INVENTION

The purposes of this invention are at least partly achieved by a method of forming a useful substrate comprising a trapping structure, the trapping structure being designed to trap charges, and/or limit crosstalk and/or radio frequency losses and/or distortion of a device that may be formed on or in the useful substrate, the method comprises the following steps:

a) supply the support substrate,

b) a step to form a first layer comprising amorphous silicon carbide on the support substrate;

c) a step to form a second layer covering the first layer, the second layer comprising an insulating or semiconductor material in an amorphous state and having a crystallisation temperature lower than that of the amorphous silicon carbide.

It is included in the method an additional heat treatment step suitable to degas the first layer and the second layer, and to crystallise the second layer and the first layer.

According to one embodiment, steps a), b) and c) are successive.

With such a method, the first layer and the second layer then forming the trapping structure, a second layer can be obtained with a low roughness, particularly at the level of the interface with an insulating layer when the interface supports such an insulating layer. Therefore it is easier to associate a useful layer with such a trapping structure, unlike the case in prior art for which there is no such reduced roughness.

For this description and in the remainder of this document, crystallisation of a layer, and particularly of the first layer, refers to partial or total crystallisation of said layer, and in particular of the first layer. Thus, in accordance with the generally accepted understanding of such crystallisation, such crystallisation includes partial crystallization and total crystallisation of said layer.

According to one embodiment, the amorphous silicon carbide forming the first layer has a carbon content of less than 50%, advantageously between 30% and 50%.

According to one embodiment, step d) also includes the performance of a heat treatment designed to crystallise the material forming the second layer exclusively.

According to one embodiment, the heat treatment is a fast thermal annealing, the fast thermal annealing comprising a temperature rise to a temperature of less than 1100° C., advantageously less than 1050° C., and with a duration of less than 10 seconds, advantageously less than 1 second.

According to one embodiment, the heat treatment may also be followed by an additional heat treatment designed to degas the first layer and the second layer.

According to one embodiment, step b) is performed in a chemical vapour phase deposition chamber, advantageously in a plasma enhanced chemical vapour phase deposition chamber.

According to one embodiment, step c) is also performed in the chemical vapour phase deposition chamber.

According to one embodiment, the method also includes the formation of an insulating layer and a semiconductor layer, in order and covering the trapping structure.

According to one embodiment, the formation of the insulating layer and the semiconductor layer includes a transfer of the insulating layer and the semiconductor layer from a donor substrate, onto the second layer.

According to one embodiment, the transfer includes the following steps:

1) supply the donor substrate;

2) a step to form the insulating layer on one face of the donor substrate;

3) a step to form an embrittlement zone in the donor substrate that, with the insulating layer, delimits the semiconductor layer;

4) a step to assemble the insulating layer on the second layer;

5) a step to fracture the donor substrate in the embrittlement zone to transfer the insulating layer and the semiconductor layer onto the second layer.

According to one embodiment, the method comprises firstly a step to supply a silicon on insulator substrate, formed from a dielectric layer and a useful layer made of a semiconductor material, and in which the method comprises the formation of a zone A2 in which the insulating layer and the semiconductor layer are preserved and a zone B2 in which the insulating layer and the semiconductor layer of the silicon on insulator substrate are replaced by monocrystalline silicon, zone A2 and zone B2 being separated by isolation trenches.

According to one embodiment, the trapping structure is formed covering monocrystalline silicon in at least one zone B2.

According to one embodiment, the trapping structure is formed in at least one of the isolation trenches, being covered by the insulating material filling these trenches, preferably the trapping structure is formed directly in contact with the substrate and defines the bottom of the isolation trenches.

According to one embodiment, the material forming the second layer includes at least one material chosen from among: HfO₂, Al₂O₃, Si₁₋ₓ,Geₓ in which x is less than 0.25.

According to one embodiment, the thickness of the first layer is between 5 nm and 50 nm.

According to one embodiment, the thickness of the first layer is between 10 nm and 50 nm.

According to one embodiment, the thickness of the second layer is between 5 nm and 15 nm.

The invention also relates to a useful substrate having a trapping structure for trapping charges, and/or limiting crosstalk and/or radio frequency losses and/or distortion of a device that may be formed on or in the trapping structure, the useful substrate comprises:
a support substrate provided with a front face,
a trapping structure covering the front face;
an insulating layer covering the trapping structure;
a semiconductor layer covering the insulating layer; the trapping structure comprising:
a first layer, said first layer comprising polycrystalline silicon carbide; and
a second layer covering the first layer, that comprises an insulating or semiconductor material in a polycrystalline state, and said material having a crystallisation temperature lower than that of amorphous silicon carbide when in the amorphous state.

According to one embodiment, a device, and particularly a radio frequency device, is formed on or in the trap-rich layer.

According to one embodiment, the amorphous silicon carbide forming the first layer has a carbon content of less than 50%, advantageously between 30% and 50%.

According to one embodiment, the thickness of the first layer is between 10 nm and 30 nm.

According to one embodiment, the thickness of the second layer is between 5 nm and 15 nm.

### BRIEF DESCRIPTION OF THE DRAWINGS

Other characteristics and advantages will become clear in the following description of a method for a trapping structure according to the invention, given as non-imitative examples, with reference to the appended drawings in which:

FIG. 1 is a diagrammatic representation of an SOI substrate known in prior art and without a trap-rich layer, in particular the SOI substrate is represented on a section plane perpendicular to a principal face of said SOI substrate;

FIG. 2 is a diagrammatic representation of an RF SOI substrate known in prior art and provided with a trap-rich layer intercalated between the insulation layer and the support substrate, in particular the RF SOI substrate is shown in a section plane perpendicular to a principal face of said SOI substrate;

FIG. 3 is a representation of a useful substrate according to this invention, in particular the useful substrate is represented in a section plane perpendicular to the front face of the support substrate;

FIG. 4 is a diagrammatic representation of steps a) and b) for forming a first layer on a front face of a support substrate according to this invention, in particular the support substrate is represented in a section plane perpendicular to a front face of the support substrate;

FIG. 5 is a diagrammatic representation of a step c) to form a second layer covering the first layer according to this invention, in particular the support substrate is represented in a section plane perpendicular to a front face of the support substrate;

FIG. 6 is a diagrammatic representation of a step 2) forming an insulating layer on a principal face of a donor substrate according to this invention, in particular the donor substrate is represented in a section plane perpendicular to a principal face of the support substrate;

FIG. 7 is a diagrammatic representation of a step 3) forming an embrittlement zone, in particular by implantation of species in the donor substrate in order to delimit the semiconductor layer in said donor substrate according to this invention, in particular the donor substrate is represented in a section plane perpendicular to a principal face of the donor substrate;

FIG. 8 is a diagrammatic representation of an assembly step 4) according to this invention, in particular the donor substrate is represented in a section plane perpendicular to a principal face of the donor substrate;

FIG. 9 is a diagrammatic representation of a fracture step 5) according to this invention, in particular the support substrate is represented in a section plane perpendicular to a front face of the support substrate;

FIG. 10 is a diagrammatic representation of a useful substrate used for hybridisation, in particular including the formation of zones A of HR SOI, and zones B of solid silicon;

FIG. 11 is a representation of a second example embodiment for forming the trapping structure according to this invention;

FIG. 12 is a representation of a third example embodiment for forming the trapping structure according to this invention,

FIG. 13 is a representation of a fourth example embodiment for forming the trapping structure according to this invention,

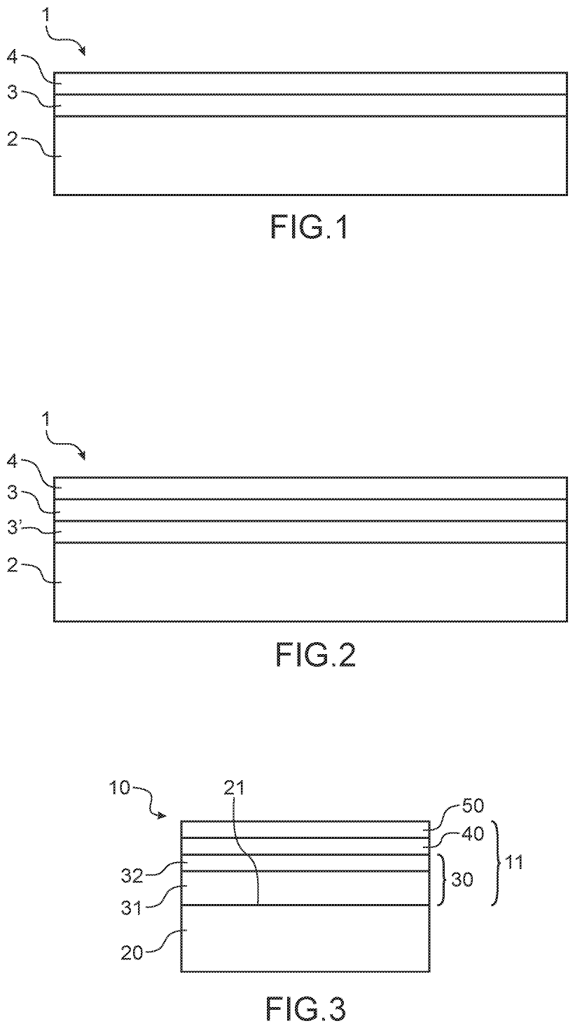

### DETAILED PRESENTATION OF PARTICULAR EMBODIMENTS

This invention relates to a method of forming a useful substrate trapping structure, and designed to trap charges, and/or limit crosstalk and/or radio frequency losses of a device that may be formed on or in the useful substrate,

The formation of the trapping structure can include the following operations in particular:

a) supply the useful substrate,

b) a step to form a first layer comprising amorphous silicon carbide on the useful substrate;

c) a step to form a second layer covering the first layer, that comprises an insulating or semiconductor material in an amorphous state and having a crystallisation temperature lower than that of the amorphous silicon carbide.

According to one possibility, not included in the invention, the insulating or semiconductor material may be in a polycrystalline state during the second layer formation stage.

In particular, the method according to this invention relates to the problem of forming a trapping structure that retains its trapping properties when subjected to significant heat treatments, and in particular that can be performed at temperatures of the order of 1000° C. or even 1100° C.

This trapping structure can advantageously be used in the framework of the formation of a useful substrate of the semiconductor on insulator type, for example for radio frequency applications (hereinafter “RF”). In this case, the useful substrate comprises a support substrate on one face of which, called the front face, a stack of layers is formed, on which there are the trapping structure, an insulating layer and a semiconductor layer, starting from the front face.

FIGS. 3 to 9 show a first example embodiment of the method of forming the trapping structure for the manufacture of a useful substrate 10 of the semiconductor on insulator type according to the invention.

In particular, as illustrated on FIG. 3, the useful substrate 10 comprises a support substrate 20 on one face of which, called the front face 21, a stack 11 of layers is formed, on which there are a trapping structure 30, an insulating layer 40 and a semiconductor layer 50, starting from the front face 21.

The trapping structure 30 comprises in particular, starting from the front face 21, a first layer 31 and a second layer 32 covering the first layer 31.

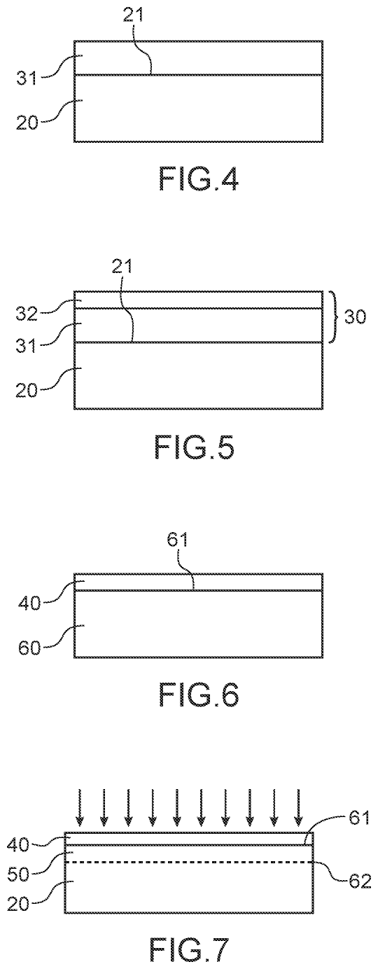

As shown in FIG. 4, the method comprises in particular a step a) for the supply of a support substrate 20.

For example, the support substrate 20 may comprise silicon, and more specifically high resistivity silicon that has a resistivity of more than 1 kOhm.cm.

However, the invention is not limited to the use of silicon alone, and a person skilled in the art may use his or her general knowledge and the following description, to consider any other type of material. For example, the substrate 20 may comprise at least materials chosen from among glass, quartz, a ceramic.

The method also includes a step b) to form a first layer 31 on a front face 21 of a support substrate 20 (FIG. 4).

The formation of the first layer 31 may be preceded by a step to clean the front face 21 before removing all traces of contaminant.

Moreover, the first layer 31 according to this invention comprises silicon carbide, advantageously with an atomic carbon content of less than 50% (it is understood that the atomic carbon content is strictly greater than 0%), advantageously between 30% and 50%.

The formation of this first layer 31 may involve a chemical vapour phase deposition, and in particular a plasma enhanced chemical vapour phase deposition. The deposition temperature can be between 320° C. and 480° C., for example 350° C.

Furthermore, the first layer 31 may be between 5 nm and 50 nm thick.

Step b) is followed by step c) to form a second layer 32 covering the first layer 31 (illustrated in FIG. 5).

This second layer 32 comprises in particular an insulating or semiconductor material in an amorphous state having a crystallisation temperature lower than that of the amorphous silicon carbide. For example, the material forming the second layer 32 may comprise at least one material chosen from among: HfO₂, Al₂O₃, Si₁₋ₓ,Geₓ in which x is less than 0.25, or amorphous silicon.

Furthermore, the second layer 32 can be between 5 nm and 15 nm thick.

The formation of this second layer 32 may comprise a chemical vapour phase deposition, for example a plasma enhanced chemical vapour phase deposition.

In a particularly advantageous way, the first layer 31 and the second layer 32 are formed in the same deposition chamber without venting the chamber. Such a sequence protects the first layer 31 from moisture after step b).

The invention is not limited to this deposition technique alone and may alternatively comprise a chemical vapour deposition of an organometallic precursor, or a deposition in atomic layers.

The method may also comprise a step d) that comprises the performance of a heat treatment intended to crystallise the material forming the second layer 32 exclusively. The size of the grains formed during crystallisation is also limited to the thickness of the second layer 32. Thus, the consideration of a second thin layer, for example with a thickness of between 5 nm and 15 nm, makes it possible to impose that the size of said grains is also within this range.

In this regard, the heat treatment may comprise a fast thermal annealing that comprises a temperature rise to a temperature of less than 1100° C., advantageously less than 1050° C., and that lasts for less than 10 seconds, advantageously less than 1 second.

This heat treatment may also be followed by an additional heat treatment designed to degas the first layer 31 and the second layer 32. This additional heat treatment, with a view to degassing layers 31 and 32, also leads to crystallisation of the first layer 31. Consideration of the second layer 32, crystallised during the heat treatment, makes it possible to limit the size of grains formed during the crystallisation of the first layer 32 during this additional heat treatment. In particular, the grains of the second layer 32 act as germs during crystallisation.

A high atomic carbon content, in particular between 30% and 50%, increases the thermal budget necessary for the crystallisation of silicon carbide, but also contributes to slowing this crystallisation. Thus, the combination of a high carbon content and the second layer according to the terms of this invention make it possible to limit the size of grains in the first layer, and to freeze their structure during subsequent heat treatments that may occur.

The method according to this invention may also include a transfer of the insulating layer 40 and the semiconductor layer 50 from a donor substrate 60 onto the second layer 32.

The transfer may include a step 1) to supply a donor substrate 60.

For example, the donor substrate 60 may comprise silicon, and particularly monocrystalline silicon. The insulating layer 40 may comprise silicon dioxide and be between about 10 nm and 1000 nm thick.

The method also includes a step 2) to form the insulating layer 40 on a face called the principal face 61 of the donor substrate 60 (FIG. 6).

The insulating layer 40 can be formed during a deposition step, or simply be the result of a thermal oxidation step of the silicon donor substrate 60.

Step 2) is followed by a step 3) to form an embrittlement zone 62 in the donor substrate 60 that, with the insulating layer 40, delimits the semiconductor layer 30 (FIG. 7). In other words, the semiconductor layer 50 extends from the principal face 61 of the donor substrate 60 with a thickness determined by the position of the embrittlement zone 62.

Formation of the embrittlement zone 62 may comprise a step to implant species, particularly light ions such as hydrogen ions and/or helium ions. For example, the dose of implanted species may be greater than 10¹⁶ atoms/cm².

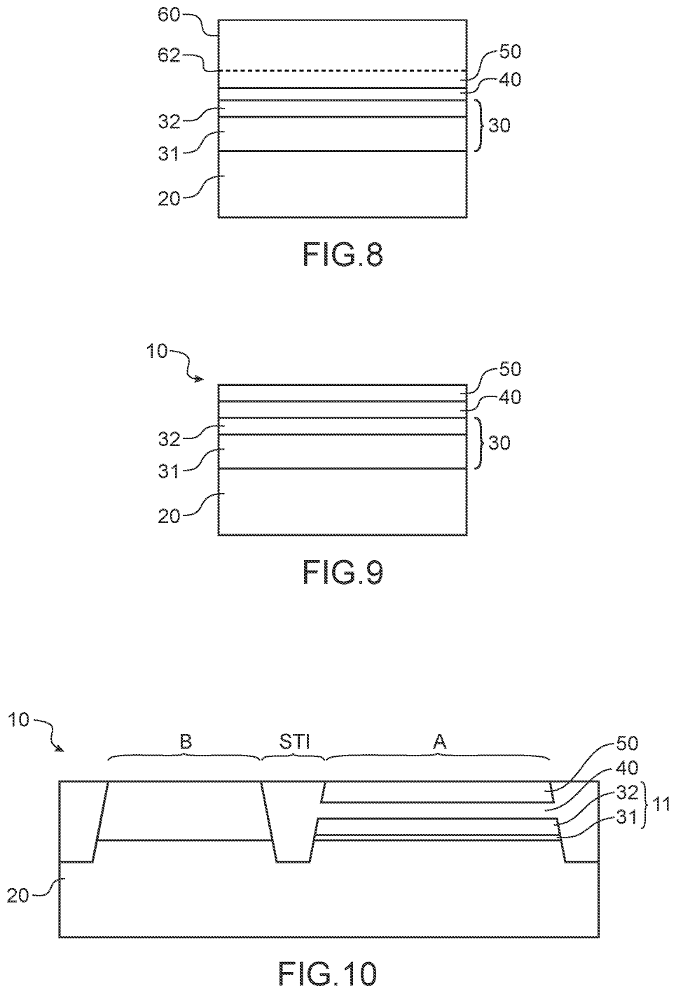

The method may also comprise a step 4) for assembling the insulating layer 40 with the second layer 32 (FIG. 8).

For example, the assembly step may comprise a molecular bonding by contact between the insulating layer 40 and the second layer 32.

Finally, step 4) may be followed by a step 5) to fracture the donor substrate at the embrittlement zone 62 so as to transfer the insulating layer 40 and the semiconductor layer 50 onto the second layer 32 (FIG. 9).

Finishing steps, such as polishing and/or heat treatments, may also be considered to reinforce the assembly interface and/or smooth the face of the semiconductor layer 50 exposed to the outside environment.

Thus the method according to this invention can be used to form a useful substrate 10 of the semiconductor on insulator type that comprises a trapping structure formed from the first layer 31 and the second layer 32.

In particular, in this invention, the first layer 31 comprises silicon carbide, in particular with an atomic carbide content between 30% and 50%. The carbon atoms contained in the first layer 31 are all trapping sites that enhance the trapping capabilities of the trapping structure 30. They also limit crystallisation of the first layer 31.

Consideration of the second layer 32, made of a material with a crystallisation temperature lower than that of amorphous silicon carbide, makes it possible to crystallise the second layer before the first layer 31. Since this layer may be thin, the grains formed during its crystallisation remain small (less than the thickness of the second layer), and act as germs for crystallisation of the silicon carbide in the first layer that may occur during thermal annealing. In other words, the size of silicon carbide grains that can be formed is governed by the grain size of the material forming the first layer.

The useful substrate 10 thus obtained may advantageously comprise a second layer 32 made of polycrystalline silicon, and a relatively thin insulation layer 40, for example between 2 nm and 25 nm thick.

This configuration known as UTBB SOI (for SOI substrate with an ultra-thin body and buried oxide layer) is also associated with a relatively thin semiconductor layer 50 (FIG. 10).

Such a UTBB SOI substrate can advantageously be used, for example, to co-integrate RF devices with logical devices. In this regard, this co-integration may involve the formation of zones “B” in which the stack 11 is replaced by monocrystalline silicon while keeping the stack 11 in zones “A”. In addition, zones “A” and “B” are advantageously separated from each other by STI isolation trenches.

The formation of zones “B” may involve firstly the production of the STI isolation trenches, then etching of the stack 11 and finally growth of monocrystalline silicon (epitaxial growth).

The consideration of relatively thin layers facilitates the etching step for the creation of hybrid zones “B”.

Advantageously, the second layer 32, that includes small grains, enables control over the variability of the threshold voltage associated with the back gate of a transistor that may be formed on or in the semiconductor layer 50.

Furthermore, the depth of the STI isolation trenches, that is greater than the total thickness of the stack 11, thus reduces the leakage paths between zones “A”.

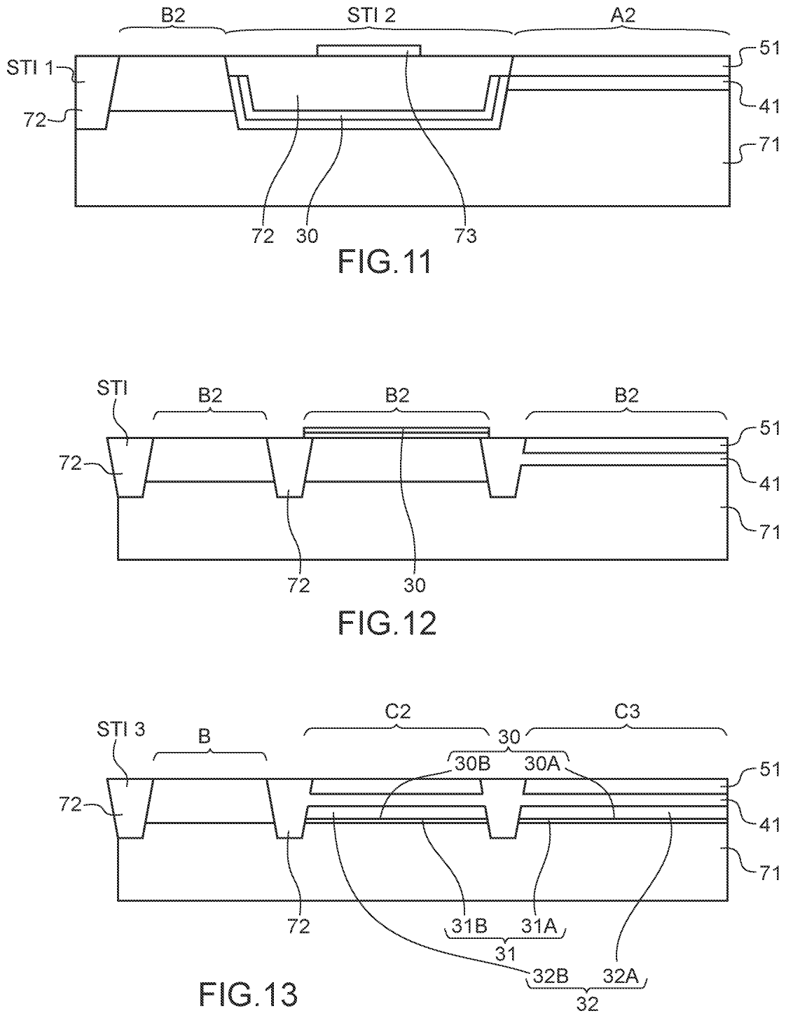

FIG. 11 shows a second example of an embodiment for forming the trapping structure 30 starting from a silicon on insulator substrate 70.

The silicon on insulator substrate 70 comprises in particular a silicon substrate 71, and a second insulating layer 41 and a second semiconductor layer 51 covering a principal face of this substrate.

This example includes the formation of first STI trenches 1 and second STI trenches 2 on a silicon on insulator substrate 70. This formation includes in particular etching of the second insulation layer 41 and the second semiconductor layer 51. In this example, the STI trenches 1 and 2 are filled with an insulating material 72, for example silicon dioxide. However, the second STI trenches 2 also comprise the trapping structure 30 intercalated between firstly the bottom part and possibly the walls of the said trench, and secondly the insulating material 72. In other words, the trapping structure 30 is formed before the insulating material 72.

Details relating to the formation of the STI trenches 1 and 2 are known to a person skilled in the art and are therefore not presented in this application.

In addition, the trapping structure 30 is formed in a manner that does not present a section exposed to the external environment. In other words, formation of the trapping structure may involve etching of the trapping structure at the walls of the second STI trenches 2.

This second embodiment may also comprise consideration of zones A2 and zones B2. In this regard, zones A2 are zones in which the second insulation layer 41 and the second semiconductor layer 51 are preserved, while these two layers 41 and 51 are replaced by monocrystalline silicon in the second zones B2.

STI 2 are then advantageously used for the formation of passive components 73, such as inductors.

FIG. 12 shows a third example of the formation of the trapping structure 30.

Like the second embodiment, the silicon on insulator substrate 70 is also considered.

This third embodiment comprises the formation of the first STI trenches 1, and hybrid zones B2 while retaining the zones A2 described above.

In this example, the trapping structure 30 is formed covering the hybrid zones B2.

The different embodiments of this invention use a trapping structure that has reduced sensitivity to heat treatments.

Furthermore, this trapping structure does not use an interface layer that can disturb interactions between free carriers and the traps of the trapping structure.

It is understood that each embodiment considered in this invention may use elements of the other embodiments presented, provided that they are compatible.

FIG. 13 illustrates a useful substrate according to a fourth example embodiment for forming the trapping structure according to this invention.

For the purpose of this example, the second layer 32 has a first region 32A and a second region 32B distinguished from each other by different concentrations of doping elements of said second material. Thus for example, the first region 32A may have a concentration of dopant elements of the unintentionally doped type, and the second region 32B may have a concentration of dopant elements of the intentionally doped type, for example because of a localised doping elements implantation step. According to this example, the second region 32B of the second layer 32 then has a higher concentration of dopant elements than the first region 32B of the second layer 32.

Obviously, without going outside the scope of the invention, it is also possible that the first and second regions 32A, 32B of the second layer 32, are both of a intentionally doped type, these regions being distinguished from each other by a concentration of doping elements. Thus, the second region 32B may have a concentration of dopant elements of the same type as that of the first region 32A of the second layer 32, for example an N (or P) type doping, with a higher concentration of said doping elements, or it may have a concentration of doping elements of a type distinct from that of the first 32A region of the second layer 32, for example the first region 32A having N type doping and the second region 32B having P type doping.

Such a presence of a first region 32A and a second region 32B with different configurations of doping elements (this difference may be related to the type of conductivity, with conductivities being opposite, or one may have one type among N and

P doping, and the other a conductivity type of the intrinsic doping type, or related to distinct concentrations for each), makes it possible for the second layer 32 to provide different functions. For example, through one of these regions 32A, 32B, the second layer 32 can provide a back gate function for field effect transistors made in the second semiconductor layer 51, and through the other region 32A, 32B, can provide a trapping zone function for components with no back gate.

As shown in FIG. 13, in this fourth example, the first region 32A of the second layer 32 with a corresponding region 31A of the first layer 31 forms a trapping substructure 30A. Similarly, the second region 32B of the second layer 32 with a corresponding region 31B of the first layer 31 forms a second trapping substructure 30B. The first trapping substructure 30A and the second trapping substructure 30B are separated from each other by an STI isolation trench 3 filled with insulating material 72.

Note that each of these trapping substructures is associated with a second insulation layer 41 and the corresponding second semiconductor layer 51. In this way, two distinct zones C2, C3 are formed in the useful substrate, one C3 associated with the first trapping substructure 30A and the other C2 associated with the second trapping substructure 30B.

According to one possibility of this fourth embodiment, and in exactly the same way as for the first, second and third example embodiments of the formation of the trapping structure according to this invention, a zone B of the useful substrate may be provided in which the second insulation layer 41 and the second semiconductor layer are replaced by monocrystalline silicon. In accordance with the first, second and third example embodiments, said zone B is separated from the two zones C2, C3 by an STI isolating trench 3 filled with insulating material 72. Such a useful substrate may be made by the use of a production method according to the invention for which:

during step d) to form the second layer 32 covering the first layer 31, the second material is an amorphous semiconductor, said second layer 32 having a first region 32A and a second region 32B distinguished from each other by a different concentration of dopant elements of said second material;

it is included the formation of at least one STI isolation trench 3 filled with an insulating material to separate the first trapping substructure 30A from the second trapping substructure 30B.

It should be noted that in this method, the step d) to form the second layer 32 may comprise a localised implantation step for at least one of the first and second regions 32A, 32B of the second layer 32 so that first region 32A and the second region 32B may be provided with different concentrations of doping elements.

According to the possibility by which a zone B of the useful substrate is provided in which the second insulation layer 41 and the second semiconductor layer are replaced by monocrystalline silicon, the method may include a later step comprising the following sub-steps:

removal of the first layer 31 and the second layer 32 on a part of the support substrate 20;

the formation of a semiconductor layer at least partially covering the part of the support substrate from which the first layer and the second layer have been removed.

### REFERENCES

[1] WO 2012/127006;

[2] WO 2017/144821;

[3] US 2016/0071959;

[4] Yoshimo Miura et al., “Paramagnetic Defects Related to Positive Charges in Silicon Oxynitride Films”, Jpn. J. Appl. Phys., Vol. 39, pp. L 987-L989, (2000).

1. A method for the formation of a useful substrate comprising a trapping structure, the trapping structure being designed to at least one of trap charges and limit at least one of crosstalk, radio frequency losses and distortion of a device formed on or in the useful substrate, comprising:
a) supplying a support substrate;
b) forming a first layer comprising amorphous silicon carbide on the support substrate;
c) forming a second layer covering the first layer, the second layer comprising an insulating or semiconductor material in an amorphous state and having a crystallisation temperature lower than that of the amorphous silicon carbide; and
d) conducting a heat treatment to degas the first layer and the second layer and to crystallise the second layer and the first layer.

2. The method for the formation of a useful substrate according to claim 1, wherein the amorphous silicon carbide forming the first layer has a carbon content of less than 50%.

3. The method for the formation of a useful substrate according to claim 1, wherein the amorphous silicon carbide forming the first layer has a carbon content of between 30% and 50%.

4. The method for the formation of a useful substrate according to claim 1, comprising performing step b) in a chemical vapour phase deposition chamber.

5. The method for the formation of a useful substrate according to claim 1, comprising performing step b) in a plasma enhanced chemical vapour phase deposition chamber.

6. The method for the formation of a useful substrate according to claim 1, the method also comprising of forming an insulating layer and a semiconductor layer, in order and covering the trapping structure.

7. The method for the formation of a useful substrate according to claim 6, wherein forming the insulating layer and the semiconductor layer includes transferring the insulating layer and the semiconductor layer from a donor substrate onto the second layer.

8. The method for the formation of a useful substrate according to claim 7, wherein transferring includes:
1) supplying the donor substrate;
2) forming the insulating layer on one face of the donor substrate;
3) forming an embrittlement zone in the donor substrate that, with the insulating layer, delimits the semiconductor layer;
4) assembling the insulating layer on the second layer and
5) fracturing the donor substrate in the embrittlement zone to transfer the insulating layer and the semiconductor layer onto the second layer.

9. The method for the formation of a useful substrate according to claim 1, comprising forming the trapping structure in at least one isolation trench, being covered by an insulating material filling this trench.

10. The method for the formation of a useful substrate according to claim 9, comprising forming the trapping structure is formed directly in contact with the substrate and defines a bottom of the at least one isolation trench.

11. The method for the formation of a useful substrate according to claim 1, wherein during forming the second layer covering the first layer, the second material of the second layer is an amorphous semiconductor, said layer having a first region and a second region distinguished from each other by a different concentration of dopant elements of said second material.

12. The method for the formation of a useful substrate according to claim 11, wherein the first region has a concentration of dopant elements of an unintentionally doped type.

13. The method for the formation of a useful substrate according to claim 11, wherein the first region of the second layer with a corresponding region of the first layer forms a trapping substructure, and the second region of the second layer with a corresponding region of the first layer forms a second trapping substructure,
the method further comprising forming at least one isolation trench filled with an insulating material to separate the first trapping substructure from the second trapping substructure.

14. The method for the formation of a useful substrate according to claim 11, further comprising the following sub-steps:
removing the first layer and the second layer on a part of the support substrate; and
forming a semiconductor layer at least partially covering the part of the support substrate from which the first layer and the second layer have been removed.

15. The method for the formation of a useful substrate according to claim 1, wherein the material forming the second layer includes at least one material chosen from among HfO₂, Al₂O₃, and Si₁₋ₓGeₓ in which x is less than 0.25.

16. The method for the formation of a useful substrate according to claim 1, wherein at least one of the first layer has a thickness of between 10 nm and 50 nm and the second layer has a thickness of between 5 nm and 150 nm.

17. A useful substrate having a trapping structure for at least one of trapping charges and limiting at least one of crosstalk, radio frequency losses and distortion of a device configured to be formed on or in the trapping structure, comprising:
a support substrate provided with a front face;
a trapping structure covering the front face;
an insulating layer covering the trapping structure; and
a semiconductor layer covering the insulating layer;
wherein the trapping structure comprises:
a first layer comprising polycrystalline silicon carbide; and
a second layer covering the first layer, that comprises an insulating or semiconductor material in a polycrystalline state, said material having a crystallisation temperature lower than that of amorphous silicon carbide when in an amorphous state.

18. The substrate according to claim 17, wherein a device is formed on or in a trap-rich layer of the trapping structure.

19. The substrate according to claim 18, wherein the device is a radio frequency device.
